(19) United States
(12) Patent Application Publication
(10) Pub. No.: US 2022/0205098 A1
(43) Pub. Date: Jun. 30, 2022

(54) ATOMIC LAYER DEPOSITION APPARATUS

(71) Applicant: BENEQ OY, Espoo (FI)

(72) Inventors: Pekka SOININEN, Espoo (FI); Hulda AMINOFF, Espoo (FI); Ville MIIKKULAINEN, Espoo (FI); Pekka J. SOININEN, Espoo (FI)

(21) Appl. No.: 17/622,340

(22) PCT Filed: Jun. 26, 2020
(86) PCT No.: PCT/FI2020/050465

§ 371 Date: Dec. 23, 2021

(30) Foreign Application Priority Data
Jun. 28, 2019 (FI) 20195590

(51) Int. Cl. C23C 16/455; C23C 16/44

(52) U.S. Cl. CPC C23C 16/45544; C23C 16/4412; C23C 16/45561

(57) ABSTRACT

An atomic layer deposition apparatus for processing substrates. The apparatus includes an atomic layer deposition reactor and one or more precursor supply sources connected to the atomic layer deposition reactor. The apparatus further includes an outer apparatus casing, the atomic layer deposition reactor and the one or more precursor sources being arranged inside the outer apparatus casing, an apparatus ventilation discharge connection arranged to discharge ventilation gas from inside of the outer apparatus casing and one or more apparatus ventilation inlet connections provided to the outer apparatus casing and arranged to provide ventilation gas into the outer apparatus casing.

### FIELD OF THE INVENTION

The present invention relates to an atomic layer deposition apparatus and more particularly to an atomic layer deposition apparatus according to the preamble on claim 1.

### BACKGROUND OF THE INVENTION

Atomic layer deposition apparatus conventionally comprises an atomic layer deposition (ALD) reactor and precursor sources for supplying precursors to the ALD reactor. The ALD reactor may have operating temperature up to 600° C. or even more. Further, the ALD apparatus comprises hot sources, solid sources or low vapor pressure sources having high operating temperature, for example up to 500° C. The precursor sources are usually provided to a precursor cabinet. These high temperatures increase the temperature of the apparatus and parts thereof causing safety issues for users and also thermal stress issues for the apparatus itself. Therefore, the ALD apparatus, and also the ALD reactor and precursors cabinet are cooled. Furthermore, many of the utilized precursor are hazardous or even toxic chemicals. Therefore, the ALD apparatus is conventionally provided with exhaust systems for exhausting precursors away from the apparatus.

In the prior art apparatuses, the ventilation gas flow or ventilation gas exhaust is designed based on the need to exhaust the hazardous precursors in different parts of the ALD apparatus, for example in the ALD reactor and in the precursor cabinet, such that safety use of the ALD apparatus may be achieved.

One of the problems associated with the prior art apparatuses is that, ventilation gas flows in different parts of the apparatus cause uncontrolled thermal loads inside apparatus as thermal energy is transported together with the ventilation gas. Furthermore, different operating temperatures of different parts of the apparatus, for example the ALD reactor and the precursor cabinet, have not been taken into account in the ventilation which has further caused uncontrolled thermal loads in the apparatus.

### BRIEF DESCRIPTION OF THE INVENTION

An object of the present invention is to provide an atomic layer deposition apparatus such that the prior art disadvantages are solved or at least alleviated.

The objects of the invention are achieved by an atomic layer deposition apparatus which is characterized by what is stated in the independent claim 1.

The preferred embodiments of the invention are disclosed in the dependent claims.

The invention is based on the idea of providing an atomic layer deposition apparatus for processing substrates according to principles of atomic layer deposition. The apparatus comprises an atomic layer deposition reactor and one or more precursor supply sources connected to the atomic layer deposition reactor for supplying precursors to the atomic layer deposition reactor.

The apparatus further comprises an outer apparatus casing. The atomic layer deposition reactor and the one or more precursor sources are arranged inside the outer apparatus casing. Therefore, the outer apparatus casing encloses both the ALD reactor and the precursor sources. The apparatus further comprises an apparatus ventilation discharge connection arranged to discharge ventilation gas from inside of the outer apparatus casing and one or more apparatus ventilation inlet connections provided to the outer apparatus casing and arranged to provide ventilation gas into the outer apparatus casing.

In the present invention, the outer apparatus casing comprises a reactor compartment comprising the atomic layer deposition reactor provided inside the reactor compartment, and a first precursor supply compartment comprising one or more precursor sources provided inside the first precursor supply compartment. The apparatus further comprises one or more first ventilation flow connections provided to the first precursor supply compartment arranged to provide ventilation gas into the first precursor supply compartment, and one or more second ventilation flow connections arranged between the first precursor supply compartment and the reactor compartment and arranged to discharge ventilation gas from the first precursor supply compartment and provide ventilation gas from the first precursor supply compartment to the reactor compartment. The apparatus ventilation discharge connection is provided to the reactor compartment and arranged to discharge ventilation gas from the reactor compartment and from inside of the outer apparatus casing.

Accordingly, the apparatus ventilation inlet connections are provided to the outer apparatus casing such that ventilation gas is received inside the outer apparatus casing via the apparatus inlet connections. Further, the apparatus ventilation discharge connection is connected or provided to outer apparatus casing such that ventilation gas is discharged from inside the outer apparatus casing via the apparatus ventilation discharge connection. Therefore, the ALD reactor and the one or more precursor sources are ventilated inside the outer apparatus casing with the same ventilation system. Therefore, possible hazardous chemical leaks and heat loads from the heated ALD reactor and heated precursor sources are exhausted in controlled manner from the apparatus.

The apparatus ventilation discharge connection comprises a pump or vacuum pump or some other suctions device which generates ventilation gas flow. The apparatus ventilation inlet connection may comprise ventilation openings via which ventilation gas, for example from the surroundings of the apparatus may be received into the outer apparatus casing.

The first precursor supply compartment is provided inside the outer apparatus casing and comprises first precursor supply compartment walls defining the first precursor supply compartment as separated compartment inside the outer apparatus casing. Ventilation gas flows inside the first precursor supply compartment via the one or more first ventilation flow connections and is further discharged out of the first precursor supply compartment via the second ventilation flow connections. Thus, a ventilation gas flow inside and through the first precursor supply compartment is generated. Accordingly, the one or more precursor sources are provided to a separate ventilated space inside the outer apparatus casing.

In one embodiment of the first precursor supply compartment, the one or more second ventilation flow connections are arranged in vertical direction above the one or more first ventilation flow connections in the first precursor supply compartment.

Due to natural convection, heated gas or air tends to raise upwards. The first precursor supply compartment comprises hot precursors sources or low vapor pressure precursor sources which are heated with precursor heaters. Thus, thermal energy is released in the first precursor supply compartment. The thermal energy heats the ventilation gas inside the first precursor supply compartment and the heated ventilation gas tends to raise upwards due to natural convection. Thus, arranging the second ventilation flow connections above the first ventilation flow connections enables efficient removal of thermal energy from the first precursor supply compartment as the removal of heated ventilation gas is carried out in direction of the natural convection. Thus, the first precursor supply compartment is arranged between the one or more apparatus ventilation inlet connections and the apparatus ventilation discharge connection. Further, first ventilation flow connections are arranged in fluid connection with the one or more apparatus ventilation inlet connections and the second ventilation flow connections are arranged in fluid connection with the apparatus ventilation discharge connection.

In one embodiment, the first precursor supply compartment is provided with a first precursor supply compartment bottom wall, a first precursor supply compartment top wall and one or more first precursor supply compartment side walls extending between the first precursor supply compartment bottom wall and the first precursor supply compartment top wall. The one or more first ventilation flow connections are arranged to the first precursor supply compartment bottom wall and the one or more second ventilation flow connections are arranged to first precursor supply compartment top wall.

In another embodiment, the first precursor supply compartment is provided with a first precursor supply compartment bottom wall, a first precursor supply compartment top wall and one or more first precursor supply compartment side walls extending between the first precursor supply compartment bottom wall and the first precursor supply compartment top wall. The one or more first ventilation flow connections are arranged to the first precursor supply compartment bottom wall and the one or more second ventilation flow connections are arranged to the one or more first precursor supply compartment side walls.

The reactor compartment comprises one or more ventilation inlet flow connections arranged to provide ventilation gas into the reactor compartment.

The reactor compartment is provided inside the outer apparatus casing and comprises reactor compartment walls defining the reactor compartment as separated compartment inside the outer apparatus casing. Ventilation gas flows inside the reactor compartment via the one or more ventilation inlet flow connections and is further discharged out of the first precursor supply compartment via the apparatus ventilation discharge connection. Thus, a ventilation gas flow inside and through the reactor compartment is generated. Accordingly, the ALD reactor is provided to a separate ventilated space inside the outer apparatus casing.

In one embodiment, the apparatus ventilation discharge connection is arranged in vertical direction above the one or more ventilation inlet flow connections in the reactor compartment.

As disclosed above, due to natural convection, heated gas or air tends to raise upwards. The reactor compartment comprises ALD reactor provided with reactor heaters for heating the ALD reactor to operating temperature. Thus, thermal energy is released in the reactor compartment. The thermal energy heats the ventilation gas inside the reactor compartment and the heated ventilation gas tends to raise upwards due to natural convection. Thus, arranging the apparatus ventilation discharge connection above the ventilation inlet flow connections enables efficient removal of thermal energy from the reactor compartment as the removal of heated ventilation gas is carried out in direction of the natural convection. Thus, highest temperature of the ALD apparatus is usually in the reactor compartment or in the ALD reactor. Therefore, discharging the ventilation gas from the reactor compartment is advantageous as the ventilation gas heated in the reactor compartment is prevented from heating other parts of the apparatus.

In one embodiment, the reactor compartment comprises a reactor compartment top wall, and the apparatus ventilation discharge connection is provided to the reactor compartment top wall and in vertical direction above the one or more ventilation inlet flow connections. Thus, the effects of natural convection may be efficiently utilized in discharging the ventilation gas from the reactor compartment and heated ventilation gas may be removed from the reactor compartment and from the outer apparatus casing.

In another embodiment, the reactor compartment comprises a reactor compartment bottom wall, a reactor compartment top wall, and one or more reactor compartment side walls extending between the reactor compartment bottom wall and reactor compartment top wall. The apparatus ventilation discharge connection is provided to the reactor compartment top wall and the one or more ventilation inlet flow connections are provided to the reactor compartment bottom wall.

In yet another embodiment, the reactor compartment comprises a reactor compartment bottom wall, a reactor compartment top wall, and one or more reactor compartment side walls extending between the reactor compartment bottom wall and reactor compartment top wall. The apparatus ventilation discharge connection is provided to the reactor compartment top wall and the one or more ventilation inlet flow connections are provided to the one or more reactor compartment side walls.

The one or more second ventilation flow connections of the first precursor supply compartment form the one or more ventilation inlet flow connections of the reactor compartment such that ventilation gas is arranged to flow from the first precursor supply compartment to the reactor compartment.

Accordingly, the ventilation gas is arranged to flow from the first precursor supply compartment to the reactor compartment via the second ventilation flow connections. Thus, the second ventilation flow connections are arranged between the first precursor supply compartment and the reactor compartment. Alternatively, the second ventilation flow connections extend or open from the first precursor supply compartment to the reactor compartment.

Usually the temperature of the precursor sources or the precursor heaters is lower than the temperature of the ALD reactor. Thus, the temperature inside the first precursor supply compartment is usually lower than the temperature in the reactor compartment. Therefore, the ventilation gas flows in direction of increasing temperature gradient inside the outer apparatus casing. Further, the ventilation gas flows upwards in the outer apparatus casing in the direction of natural convection.

In another embodiment, the first precursor supply compartment and the reactor compartment are connected to each other. The one or more second ventilation flow connections of the first precursor supply compartment form one or more ventilation inlet flow connections of the reactor compartment such that ventilation gas is arranged to flow from the first precursor supply compartment to the reactor compartment.

In one embodiment, the reactor compartment and the first precursor supply compartment are arranged adjacent to each other in horizontal direction. In an alternative embodiment, the reactor compartment is arranged at least partly above the first precursor supply compartment in vertical direction.

In one embodiment, the one or more first ventilation flow connections of the first precursor supply compartment are arranged to form the one or more ventilation inlet connections of the apparatus and arranged to provide ventilation gas into the outer apparatus casing and into the first precursor supply compartment.

Accordingly, the ventilation gas is received inside the outer apparatus casing via the one or more first ventilation flow connections of the first precursor supply compartment. This provides efficient ventilation and heat transfer from the first precursor supply compartment.

In one embodiment, the outer apparatus casing comprises an instrumentation compartment comprising apparatus instrumentation elements. The instrumentation compartment comprises the one or more ventilation inlet connections arranged to provide ventilation gas into the outer apparatus casing and into the instrumentation compartment, and one or more ventilation outlet flow connections arranged to discharge ventilation gas from the instrumentation compartment.

The instrumentation compartment is provided inside the outer apparatus casing and comprises instrumentation compartment walls defining the instrumentation compartment as separated compartment inside the outer apparatus casing. Ventilation gas flows inside the instrumentation compartment via the one or more apparatus ventilation inlet connections and is further discharged out of the instrumentation compartment via the ventilation outlet flow connections. Thus, a ventilation gas flow inside and through the instrumentation compartment is generated. Accordingly, the apparatus instrumentation elements are provided to a separate ventilated space inside the outer apparatus casing.

The apparatus instrumentation elements comprise one or more of the following: electric components of the ALD apparatus, gas connections for gaseous precursor or carrier gases or purge gases, mass flow controller, inlet channel to the ALD reactor, discharge channel from the ALD reactor, filter in connection with the discharge channel, lifting device for opening and closing a reaction chamber of the ALD reactor and other process instruments and instrumentation elements.

Accordingly, the apparatus instrumentation elements are provided into inside the instrumentation compartment and are thus arranged a separate ventilated space in the apparatus and within the outer apparatus casing.

In one embodiment, the one or more ventilation outlet flow connections are arranged in vertical direction above the one or more apparatus ventilation inlet connections in the instrumentation compartment.

Due to natural convection, heated gas or air tends to raise upwards. The instrumentation compartment comprises for example electrical components and other instrumentation elements generating thermal energy during operating the apparatus. Thus, thermal energy is released in the instrumentation compartment. The thermal energy heats the ventilation gas inside the instrumentation compartment and the heated ventilation gas tends to raise upwards due to natural convection. Thus, arranging the ventilation outlet flow connections above the apparatus ventilation inlet connections enables efficient removal of thermal energy from the instrumentation compartment as the removal of heated ventilation gas is carried out in direction of the natural convection.

In one embodiment, the instrumentation compartment comprises an instrumentation compartment bottom wall, and the one or more ventilation inlet connections are provided to the instrumentation compartment bottom wall. The one or more ventilation outlet flow connections are arranged in vertical direction above the one or more ventilation inlet connections in the instrumentation compartment.

In another embodiment, the instrumentation compartment comprises an instrumentation compartment bottom wall, an instrumentation compartment top wall and one or more instrumentation compartment side walls extending between the instrumentation compartment bottom wall and the instrumentation compartment top wall. The one or more ventilation inlet connections are provided to the instrumentation compartment bottom wall and the one or more ventilation outlet flow connections are provided to the instrumentation compartment top wall.

In yet another embodiment, the instrumentation compartment comprises an instrumentation compartment bottom wall, an instrumentation compartment top wall and one or more instrumentation compartment side walls extending between the instrumentation compartment bottom wall and the instrumentation compartment top wall. The one or more ventilation inlet connections are provided to the instrumentation compartment bottom wall and the one or more ventilation outlet flow connections are provided to the one or more instrumentation compartment side walls.

In one embodiment, one or more ventilation outlet flow connections of the instrumentation compartment form one or more first ventilation flow connections of the first precursor supply compartment such that ventilation gas is arranged to flow from the of the instrumentation compartment to the first precursor supply compartment.

Accordingly, the ventilation gas is arranged to flow into the outer apparatus casing and inside the instrumentation compartment through the apparatus ventilation inlet connections from outside of the apparatus. Further the ventilation gas arranged to flow from the instrumentation compartment to the first precursor supply compartment via the first ventilation flow connections. Thus, the first ventilation flow connections are arranged between the instrumentation compartment and the first precursor supply compartment. Alternatively, the first ventilation flow connections extend or open from the instrumentation compartment to the first precursor supply compartment.

Usually the temperature of the precursor sources or the precursor heaters is higher than the temperature of the instrumentation elements of the apparatus. Thus, the temperature inside the first precursor supply compartment is usually higher than the temperature in the instrumentation compartment. Therefore, the ventilation gas flows in direction of increasing temperature gradient inside the outer apparatus casing. Further, the ventilation gas flows upwards in the outer apparatus casing in the direction of natural convection.

In another embodiment, the instrumentation compartment and the first precursor supply compartment are connected to each other. The one or more ventilation outlet flow connections of the instrumentation compartment form one or more first ventilation flow connections of the first precursor supply compartment such that ventilation gas is arranged to flow from the instrumentation compartment to the first precursor supply compartment.

In one embodiment, the instrumentation compartment and the first precursor supply compartment are arranged adjacent to each other in horizontal direction. In an alternative embodiment, the first precursor supply compartment is arranged at least partly above the instrumentation compartment in vertical direction.

Accordingly, the ventilation gas is received inside the outer apparatus casing via the one or more ventilation inlet connections of the instrumentation compartment. This provides efficient ventilation and heat transfer from the instrumentation compartment in which the temperature is usually lower than in the first precursor supply compartment and in the reactor compartment.

In one embodiment, the instrumentation compartment and the first precursor supply compartment are connected to each other, and that one or more ventilation outlet flow connections of the instrumentation compartment form one or more first ventilation flow connections of the first precursor supply compartment such that ventilation gas is arranged to flow from the of the instrumentation compartment to the first precursor supply compartment.

In one embodiment of the apparatus, one or more ventilation outlet flow connections of the instrumentation compartment form one or more ventilation inlet flow connections of the reactor compartment such that ventilation gas is arranged to flow from the of the instrumentation compartment to the reactor compartment.

Accordingly, a portion of the ventilation gas flows directly from the instrumentation compartment to the reactor compartment without flow through the first precursor supply compartment. Therefore, the ventilation gas may be distributed from the instrumentation compartment to the first precursor supply compartment and to the reactor compartment. In the first precursor supply compartment temperature of the ventilation gas increases and thus a portion of the ventilation gas may be supplied to the reactor compartment in lower temperature as it does not flow through the first precursor supply compartment.

In another embodiment, the instrumentation compartment and the reactor compartment are connected to each other, and that one or more ventilation outlet flow connections of the instrumentation compartment form one or more first ventilation inlet flow connections of the reactor compartment such that ventilation gas is arranged to flow from the of the instrumentation compartment to the reactor compartment.

In one embodiment, the instrumentation compartment and the reactor compartment are arranged adjacent to each other in horizontal direction. In an alternative embodiment, the reactor compartment is arranged at least partly above the instrumentation compartment in vertical direction.

In one embodiment of the apparatus according to the present invention, the outer apparatus casing comprises the instrumentation compartment enclosing apparatus instrumentation elements, the first precursor supply compartment enclosing one or more precursor sources and the reactor compartment enclosing the atomic layer deposition reactor. The mentioned compartments are separated from each other with compartment walls within the outer apparatus casing.

The one or more apparatus ventilation inlet connections are provided to the instrumentation compartment and arranged to provide ventilation gas into the instrumentation compartment and inside the outer apparatus casing. One or more first ventilation flow connections are arranged between the instrumentation compartment and the first precursor supply compartment and arranged to provide ventilation gas flow from the instrumentation compartment to the first precursor supply compartment. One or more second ventilation flow connections are arranged between the first precursor supply compartment and the reactor compartment and arranged to provide ventilation gas flow from the first precursor supply compartment to the reactor compartment. Further, the apparatus ventilation discharge connection is arranged to the reactor compartment and arranged to discharge ventilation gas from reactor compartment and from inside of the outer apparatus casing.

Accordingly, the ventilation gas transported through the apparatus in order: the instrumentation compartment, the first precursor supply compartment and the reactor compartment. During operation of the apparatus, temperature inside the first precursor supply compartment is higher than in the instrumentation compartment. Similarly, the temperature in the reactor compartment is higher than in the first precursor supply compartment. Therefore, the ventilation gas flows through the apparatus and the compartments in direction of increasing temperature and an increasing temperature gradient is achieved for the ventilation gas. Thus, the instrumentation elements in the instrumentation compartment and the precursor sources in the first precursor supply compartment are not subjected to higher temperatures of the reactor compartment and the first precursor supply compartment, respectively, by the ventilation gas.

In one embodiment, the apparatus the one or more first ventilation flow connections are arranged in vertical direction above the one or more apparatus ventilation inlet connections, the one or more second ventilation flow connections are arranged in vertical direction above the one or more first ventilation flow connections, and the apparatus ventilation discharge connection is arranged in vertical direction above the one or more second ventilation flow connections.

Accordingly, natural convection is utilized in ventilation system such that ventilation gas flows upwards in vertical direction in the apparatus at the same time the temperature of the ventilation gas increases. Thus, efficient the removal of excessive heat from the apparatus is achieved.

In one embodiment, the first precursor supply compartment comprises at least one precursor heater arranged to heat the precursor source inside the first precursor supply compartment. Alternatively, the precursor heater(s) is provided to the precursor source(s).

In one embodiment, the reactor compartment or the atomic layer deposition reactor comprises at least one reactor heater arranged to heat the atomic layer deposition reactor inside the reactor compartment. The reactor heater is arranged inside the ALD reactor, or inside a vacuum chamber of the ALD reactor.

In one embodiment, the first precursor supply compartment comprises at least one precursor heater arranged to heat the precursor source inside the first precursor supply compartment, and the reactor compartment or the atomic layer deposition reactor comprises at least one reactor heater arranged to heat the atomic layer deposition reactor inside the reactor compartment.

The reactor heaters have preferably higher power output and higher operating temperature than the precursor heaters, as the operating temperature of the ALD reactor is usually higher than the temperature required for the precursor sources.

In one embodiment, the first precursor supply compartment comprises first and second precursor sources arranged spaced apart from each other such that a flow gap is provided between the first and second precursor sources. Each of the first and second precursor sources comprise a precursor heater.

The flow gap enables separating the first and second precursor sources thermally from each other. Thus, when the first and second precursor sources are provided with different precursor materials they may be heated to different temperatures and the different temperatures do not disturb each other.

In another embodiment, the first precursor supply compartment comprises a first precursor source and a valve unit. The first precursor source is closer to the one or more first flow connections than the valve unit and the valve unit is closer to the one or more second flow connections than the first precursor source. The first precursor source comprises a precursor heater. The valve unit comprises a valve unit heater.

Accordingly, when the first precursor source and the valve are operated in different temperatures, the valve unit having higher operating temperature may be arranged downstream of the first precursor source in the flow direction of the ventilation gas between the first and second ventilation flow connections and inside the first precursor supply compartment Thus, the first precursor source may be prevented to be subjected to higher temperature of the valve. The temperature of the valve unit is usually arranged higher than the temperature of the precursor source(s).

In one embodiment, the first precursor supply compartment comprises first and second precursor sources arranged spaced apart from each other such that a flow gap is provided between the first and second precursor sources, and a valve unit. The two first precursor sources are closer to the one or more first flow connections than the valve unit and the valve unit is closer to the one or more second flow connections than the first and second precursor sources. The first and the second precursor sources comprising precursor heaters. The valve unit comprises a valve unit heater.

In one embodiment, the reactor compartment comprises a reactor ventilation inlet arrangement arranged to provide ventilation gas into the reactor compartment and to the outer apparatus casing from outside of the outer apparatus casing.

Accordingly, the reactor compartment is provided with additional reactor ventilation inlet arrangement or reactor ventilation inlet connection which provides ventilation gas into the reactor compartment directly outside the outer apparatus casing. This is advantageous, as highest temperature in the apparatus is in the ALD reactor and thus, demands for ventilation and cooling is highest in the ALD reactor and in the reactor compartment. The additional reactor ventilation inlet arrangement or reactor ventilation inlet connection may be provided to the reactor compartment walls or to a door or door assembly of the ALD reactor.

In one embodiment, the atomic layer deposition reactor comprises a reactor door assembly arranged to form at least part of one side wall of the reactor compartment. The door assembly comprises a reactor ventilation inlet connection arranged to provide ventilation gas into the reactor compartment and to the outer apparatus casing from outside of the outer apparatus casing.

In one embodiment of the invention, the outer apparatus casing comprises one or more of the following:
the one or more ventilation inlet connections are arranged in horizontal direction spaced apart from the one or more ventilation outlet flow connections in the instrumentation compartment;
one or more first ventilation flow connections are arranged in horizontal direction spaced apart from the one or more second ventilation flow connections in the of the first precursor supply compartment;
one or more ventilation inlet flow connections are arranged in horizontal direction spaced apart from the apparatus ventilation discharge connection in the reactor compartment; and
the reactor ventilation inlet connection is arranged in horizontal direction spaced apart from the apparatus ventilation discharge connection in the reactor compartment.

Arranging in the compartments the ventilation inlet and the ventilation outlet spaced apart from each other in horizontal direction, or in opposite sides or opposite ends of the compartment, the ventilation gas flows through the whole compartment providing efficient ventilation.

An advantage of the invention is that one ventilation system enables efficient removal of excessive heat from the apparatus and provides necessary cooling for different parts and components of the apparatus. At the same time the thermal loads to different components of the apparatus may be minimized. Further, the same ventilation system enables discharging hazardous chemicals from the apparatus and preventing them from escaping to atmosphere in a case of a leak. Additionally, the ventilation gas flows through the apparatus and the outer apparatus casing in a direction of increasing temperature gradient. The ventilation gas is further discharged from the apparatus and from the outer apparatus casing from the reactor compartment in which the temperature is highest within the apparatus.

### BRIEF DESCRIPTION OF THE DRAWINGS

The invention is described in detail by means of specific embodiments with reference to the enclosed drawings, in which

FIG. 1 shows schematically a front view of one embodiment of an atomic layer deposition apparatus according to the present invention;

FIG. 2 shows schematically a side of the atomic layer deposition apparatus of FIG. 1;

FIG. 3 shows schematically a front view of another embodiment of an atomic layer deposition apparatus according to the present invention;

FIG. 4 shows schematically a front view of yet another embodiment of an atomic layer deposition apparatus according to the present invention;

FIG. 5 shows schematically ventilation gas flow in the atomic layer deposition apparatus of FIG. 4;

FIG. 6 shows schematically an instrumentation compartment of one atomic layer deposition apparatus according to the present invention;

FIG. 7 shows schematically a precursor supply compartment of one atomic layer deposition apparatus according to the present invention;

FIGS. 8A, 8B and 8C show schematically a more detailed embodiment of one atomic layer deposition apparatus according to the present invention;

FIG. 9 shows schematically a front view of still another embodiment of an atomic layer deposition apparatus according to the present invention;

FIG. 10 shows schematically a side view of one embodiment of a reactor compartment of an atomic layer deposition apparatus according to the present invention; and

FIG. 11 shows schematically a front view of still another embodiment of an atomic layer deposition apparatus according to the present invention.

### DETAILED DESCRIPTION OF THE INVENTION

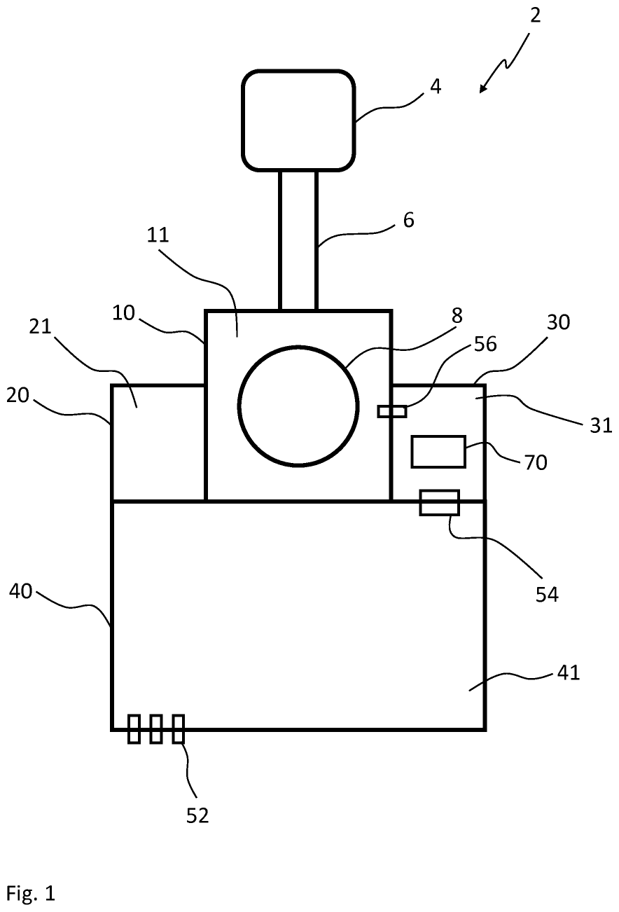

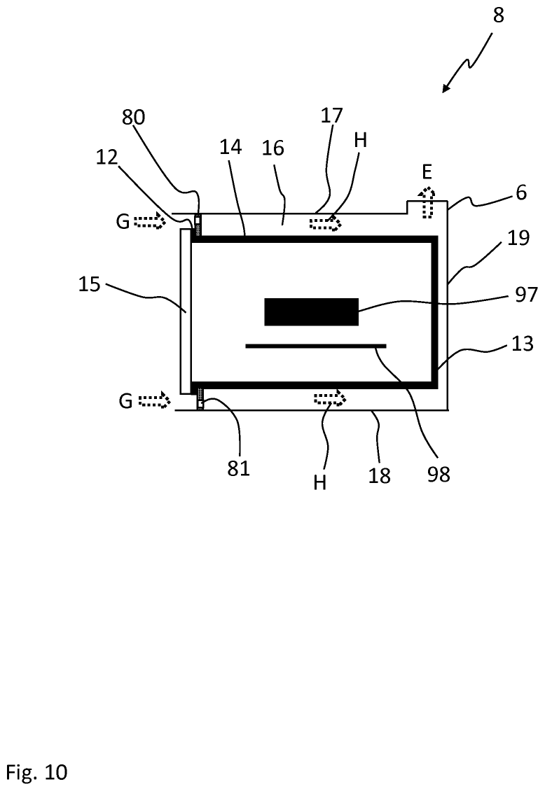

FIG. 1 shows schematically one embodiment of an atomic layer deposition apparatus 2 according to the present invention. The apparatus comprises an atomic layer deposition reactor 8. The ALD reactor may comprise a vacuum chamber 14 and a separate reaction chamber 97 arranged inside the vacuum chamber 14, as shown in FIG. 10. However, the separate reaction chamber 97 may also be omitted and the vacuum chamber 14 may form also the reaction chamber 14. The ALD apparatus further comprises one or more precursor sources 70 arranged to supply precursors to the ALD reactor 8. The precursor sources 70 are configured to received precursor containers comprising the precursor materials to be supplied to the ALD reactor 8. Accordingly, in the context of this application the term ALD reactor means the vacuum chamber 14 and the reaction chamber 97, or only reaction chamber 97.

The apparatus 2 further comprises an outer apparatus casing 10, 20, 30, 40 enclosing the ALD reactor 8 and the precursor sources 70. Thus, the ALD reactor 8 and the precursor sources 70 are arranged inside the outer apparatus casing 10, 20, 30, 40.

The outer apparatus casing 10, 20, 30, 40 comprises out apparatus casing walls 10, 20, 30, 40 defining a casing space inside the outer apparatus casing 10, 20, 30, 40. The casing walls provide or define a closed space inside the outer apparatus casing 10, 20, 30, 40, the casing space.

The outer apparatus casing 10, 20, 30, 40 is provided with an apparatus ventilation discharge connection 4, 6 arranged to discharge ventilation gas from inside of the outer apparatus casing 10, 20, 30, 40. The apparatus ventilation discharge connection 4, 6 is connected to the outer apparatus casing 10, 20, 30, 40 and/or outer apparatus casing walls 10, 20, 30, 40 thereof, as shown in FIG. 1. The apparatus ventilation discharge connection 4, 6 is open to the casing space inside the outer apparatus casing 10, 20, 30, 40 such that ventilation gas may be discharged from the casing space inside the outer apparatus casing 10, 20, 30, 40.

In the embodiment of FIG. 1, the apparatus ventilation discharge connection 4, 6, comprises a pump, vacuum pump, suction device 4 or the like discharge device arranged to provide suction to the casing space inside the outer apparatus casing 10, 20, 30, 40 for discharging the ventilation gas. It should be noted that the discharge device 4 may be any suitable device capable of providing suction to the casing space.

The discharge device 4 is connected to the outer apparatus casing 10, 20, 30, 40 with a discharge outlet 6. The discharge outlet 6 is open to the casing space inside the outer apparatus casing 10, 20, 30, 40. The discharge outlet thus is provided between the discharge device 4 and the outer apparatus casing 10, 20, 30, 40. The discharge outlet 4 may be discharge channel extending from the outer apparatus casing 10, 20, 30, 40 or discharge opening provided to the outer apparatus casing walls 10, 20, 30, 40.

The outer apparatus casing 10, 20, 30, 40 is further provided with one or more apparatus ventilation inlet connections 52. The apparatus ventilation inlet connections 52 are provided to the outer apparatus casing walls 10, 20, 30, 40 and are one to the casing space inside the outer apparatus casing 10, 20, 30, 40. The one or more apparatus ventilation inlet connections are in fluid communication with the apparatus ventilation discharge connection 4, 6 inside the outer apparatus casing 10, 20, 30, 40 and in the casing space such that the suction provided by the apparatus ventilation discharge connection generates ventilation gas flow into the casing space inside the outer apparatus casing 10, 20, 30, 40 via the apparatus ventilation inlet connections 52.

The apparatus ventilation inlet connection(s) 52 are open to the casing space inside the outer apparatus casing 10, 20, 30, 40. The apparatus ventilation inlet connection(s) 52 may be inlet channel(s) or inlet opening(s) provided to the outer apparatus casing walls 10, 20, 30, 40.

The apparatus ventilation inlet connection(s) 52 may be open to the surrounding atmosphere of the ALD apparatus for providing ventilation air or gas flow inside the apparatus ventilation inlet connection(s) 52. Alternatively, the apparatus ventilation inlet connection(s) 52 is connected to the ventilation gas source (not shown), such as gas container, for providing ventilation gas flow into the apparatus ventilation inlet connection(s) 52.

The apparatus ventilation discharge connection 4, 6 generates a ventilation gas flow through the casing space inside the outer apparatus casing 10, 20, 30, 40 from the apparatus ventilation inlet connection(s) 52 to the apparatus ventilation discharge connection 4, 6.

The ALD reactor and the precursor sources are provided inside the casing space of the outer apparatus casing 10, 20, 30, 40 and thus they are arranged inside ventilated casing space.

As shown in FIG. 1, the outer apparatus casing 10, 20, 30, 40 is divided into compartments inside the casing space. In the embodiment of FIG. 1, the outer apparatus casing 10, 20, 30, 40 comprises an instrumentation compartment 40 having instrumentation compartment walls 40 defining an instrumentation compartment space 41. The instrumentation compartment provides a closed and separated compartment space inside the casing space of the outer apparatus casing 10, 20, 30, 40.

As shown in FIG. 1, the apparatus ventilation inlet connection(s) 52 are provided to the instrumentation compartment or the instrumentation compartment walls 40. The apparatus ventilation inlet connection(s) 52 are open to the instrumentation compartment space 41. Thus, the ventilation gas is arranged to enter inside the outer apparatus casing 10, 20, 30, 40 via the apparatus ventilation inlet connection(s) 52 into the instrumentation compartment space 41.

The instrumentation compartment 40 further comprises one or more first ventilation flow connections 54 arranged to discharge ventilation gas from the instrumentation compartment 40. The one or more first ventilation flow connections 54 are open to the instrumentation compartment space 41 and in fluid communication with the apparatus ventilation discharge connection 4, 6. Thus, the suction or vacuum provided by the apparatus ventilation discharge connection generates a ventilation gas flow inside and through the instrumentation compartment 40 from the apparatus ventilation inlet connection(s) 52 to the one or more first ventilation flow connections 54.

The one or more first ventilation flow connections 54 may be openings or channels provided to the instrumentation compartment or the instrumentation compartment walls 40 and open to the instrumentation compartment space 41.

The outer apparatus casing 10, 20, 30, 40 is further divided to a first precursor supply compartment 30 and thus further comprises the first precursor supply compartment 30 comprising one or more precursor sources 70 provided inside the first precursor supply compartment. The first precursor supply compartment 30 comprises first precursor supply compartment walls 30 defining a first precursor supply compartment space 31. The first precursor supply compartment provides a closed and separated compartment space inside the casing space of the outer apparatus casing 10, 20, 30, 40.

As shown in FIG. 1, the first precursor supply compartment 30 comprises the first ventilation flow connections 54. Thus, the first ventilation flow connections 54 are provided between the instrumentation compartment 40 and the first precursor supply compartment 30. Thus, the first ventilation flow connections are open to the first precursor supply compartment 30 and also to the instrumentation compartment 40 and the first precursor supply compartment space 31.

Therefore, the ventilation gas flows from the instrumentation compartment 40 to the first precursor supply compartment 30 through the first ventilation flow connections 54. The first ventilation flow connections 54 are arranged in flow connection with the apparatus ventilation inlet connections 52 and with the apparatus ventilation discharge connection 4, 6.

The first ventilation flow connections 54 may be formed as opening or channel between the instrumentation compartment 30 and the first precursor supply compartment 30 such that the first ventilation flow connections are open to the instrumentation compartment space 41 and the first precursor supply compartment space 31. Accordingly, the first ventilation flow connections provide a flow path between the instrumentation compartment 40 and the first precursor supply compartment 30.

In one embodiment, the instrumentation compartment 40 and the first precursor supply compartment 30 have a common compartment wall, as shown in FIG. 1, and the first ventilation flow connections 54 are provided to the common compartment wall. Alternatively, the one or more first ventilation flow connections 54 may be provided as channels extending between the instrumentation compartment wall 40 and the first precursor supply compartment wall 30.

The first precursor supply compartment 30 further comprises one or more second ventilation flow connections 56 arranged to discharge ventilation gas from the first precursor supply compartment 30. The one or more second ventilation flow connections 56 are open to the first precursor supply compartment space 31 and in fluid communication with the apparatus ventilation discharge connection 4, 6. Thus, the suction or vacuum provided by the apparatus ventilation discharge connection 4, 6 generates a ventilation gas flow inside and through the first precursor supply compartment 30 from the one or more first ventilation flow connections 54 to the one or more second ventilation flow connections 56.

The outer apparatus casing 10, 20, 30, 40 is further divided to a reactor compartment 10 and thus further comprises the reactor compartment 10 comprising the ALD reactor 8 provided inside the reactor compartment 10. The reactor compartment 10 comprises reactor compartment walls 10 defining a reactor compartment space 11. The reactor compartment 10 provides a closed and separated compartment space inside the casing space of the outer apparatus casing 10, 20, 30, 40.

As shown in FIG. 1, the reactor compartment 10 comprises the second ventilation flow connections 56. Thus, the second ventilation flow connections are provided between the reactor compartment 10 and the first precursor supply compartment 30. Thus, the second ventilation flow connections 56 are open to the first precursor supply compartment 30 and also to the reactor compartment 10 and the reactor compartment space 11.

Therefore, the ventilation gas flows from the first precursor supply compartment 30 to the reactor compartment 10 through the second ventilation flow connections 56. The second ventilation flow connections 56 are arranged in flow connection with the apparatus ventilation inlet connections 52 and with the apparatus ventilation discharge connection 4, 6.

The second ventilation flow connections 56 may be formed as opening or channel between the reactor compartment 10 and the first precursor supply compartment 30 such that the second ventilation flow connections 56 are open to the reactor compartment space 11 and the first precursor supply compartment space 31. Accordingly, the first ventilation flow connections provide a flow path between the reactor compartment 10 and the first precursor supply compartment 30.

In one embodiment, the reactor compartment 10 and the first precursor supply compartment 30 have a common compartment wall, as shown in FIG. 1, and the second ventilation flow connections 56 are provided to the common compartment wall. Alternatively, the one or more second ventilation flow connections 56 may be provided as channels extending between the reactor compartment wall 10 and the first precursor supply compartment wall 30.

The reactor compartment 10 further comprises the apparatus ventilation discharge connection 4, 6. The apparatus ventilation discharge connection 4, 6 is arranged to discharge ventilation gas from inside of the outer apparatus casing 10, 20, 30, 40 and from the reactor compartment 10. The apparatus ventilation discharge connection 4, 6 is connected to the reactor compartment 10 or the reactor compartment walls 10. The apparatus ventilation discharge connection 4, 6 is open to the reactor compartment space 11 inside the reactor compartment 10 such that ventilation gas may be discharged from the reactor compartment space 11 inside the reactor compartment 10. Further, the ventilation gas is discharged from the apparatus and from the outer apparatus casing 10, 20, 30, 40 via the reactor compartment 10.

Accordingly, the reactor compartment 10, the first precursor supply compartment 30 and the instrumentation compartment 40 are in fluid communication with each other. The apparatus discharge connection 4, 6 generates a suction and ventilation gas flow from the apparatus ventilation inlet connections 52 via the instrumentation compartment 40, the first precursor supply compartment 30 and the reactor compartment 10 to the apparatus ventilation discharge connection 4, 6.

As shown in FIG. 1, the one or more first ventilation flow connections 54 are arranged in vertical direction above the one or more apparatus ventilation inlet connections 52. Similarly, the one or more second ventilation flow connections 56 are arranged in vertical direction above the one or more first ventilation flow connections 54. Further, the apparatus ventilation discharge connection 4, 6 is arranged in vertical direction above the one or more second ventilation flow connections 56. Thus, the ventilation gas flows upwards as it flows through the compartments 40, 30, and 10 and the outer apparatus casing.

The instrumentation compartment 40 is arranged below the first precursor supply compartment 30 and the reactor compartment 10 in vertical direction. However, the first precursor supply compartment 30 and the instrumentation compartment 40 may also be arranged at least partly adjacent to each other in horizontal direction. Alternatively, the first precursor supply compartment 30 is arranged partly above the instrumentation compartment 40 in vertical direction.

The first precursor supply compartment 30 and the instrumentation compartment 40 are connected to each other such that they have common compartment wall. However, alternatively they may be provided as separate compartment without common compartment walls.

The instrumentation compartment 40 is arranged below the reactor compartment 10 in vertical direction. However, the reactor compartment 10 and the instrumentation compartment 40 may also be arranged at least partly adjacent to each other in horizontal direction. Alternatively, the reactor compartment 10 is arranged partly above the instrumentation compartment 40 in vertical direction.

The reactor compartment 10 and the instrumentation compartment 40 are connected to each other such that they have common compartment wall. However, alternatively they may be provided as separate compartment without common compartment walls.

The reactor compartment 10 is arranged adjacent to the first precursor supply compartment 30 in vertical direction. Alternatively, reactor compartment 10 may be arranged above or at least partly above the first precursor supply compartment 30 in vertical direction.

The first precursor supply compartment 30 and the reactor compartment 10 are connected to each other such that they have common compartment wall. However, alternatively they may be provided as separate compartment without common compartment walls.

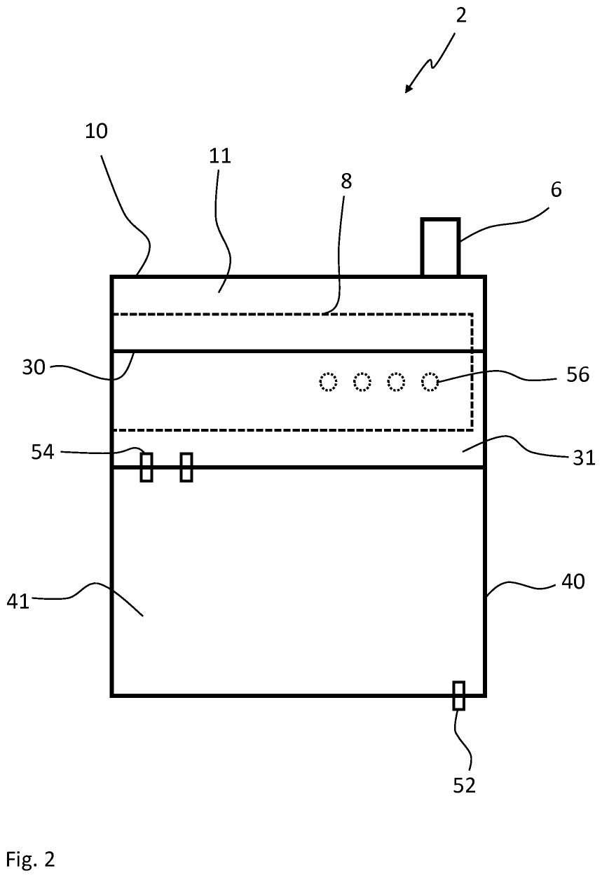

FIG. 2 shows a side of the ALD apparatus of FIG. 1. As shown in the embodiment of FIGS. 1 and 2, the instrumentation compartment 40 is arranged below the reactor compartment 10 and the first precursor supply compartment 30. The reactor compartment 10 and the first precursor supply compartment 30 are arranged adjacent to each other. The reactor compartment 10 is higher in vertical direction than the first precursor supply compartment 30, and thus the reactor compartment 10 is at least partly above the first precursor supply compartment 30. Further, the apparatus ventilation discharge connection 4, 6 is arranged in vertical direction above the one or more second ventilation flow connections 56.

As shown in FIG. 1, the ALD apparatus further comprises a second precursor supply compartment 20 having second precursor supply compartment walls 20 defining a second precursor supply compartment space 21 inside the second precursor supply compartment 20. In the embodiment of FIG. 1, the second precursor supply compartment 20 is separate from the other compartments 10, 30, 40 and the ventilation gas is prevented from entering the second precursor supply compartment 20. Accordingly, the second precursor supply compartment 20 is not provided inside the outer apparatus casing 10. Thus, the second precursor supply compartment 20 is not ventilated.

The second precursor supply compartment 20 may be provided with one or more precursor sources which may be liquid precursor sources having high vapor pressure. Thus, there is no need for cooling with ventilation gas.

It should be noted, that the second precursor supply compartment 20 may alternatively be provided similar as the first precursor supply compartment 30. Thus, the second precursor supply compartment 20 and the instrumentation compartment 40 may be provided with first ventilation flow connections 54 between the second precursor supply compartment 20 and the instrumentation compartment 40. Further, the second precursor supply compartment 20 and the reactor compartment 10 may be provided with second ventilation flow connections 56 between the second precursor supply compartment 20 and the reactor compartment 10.

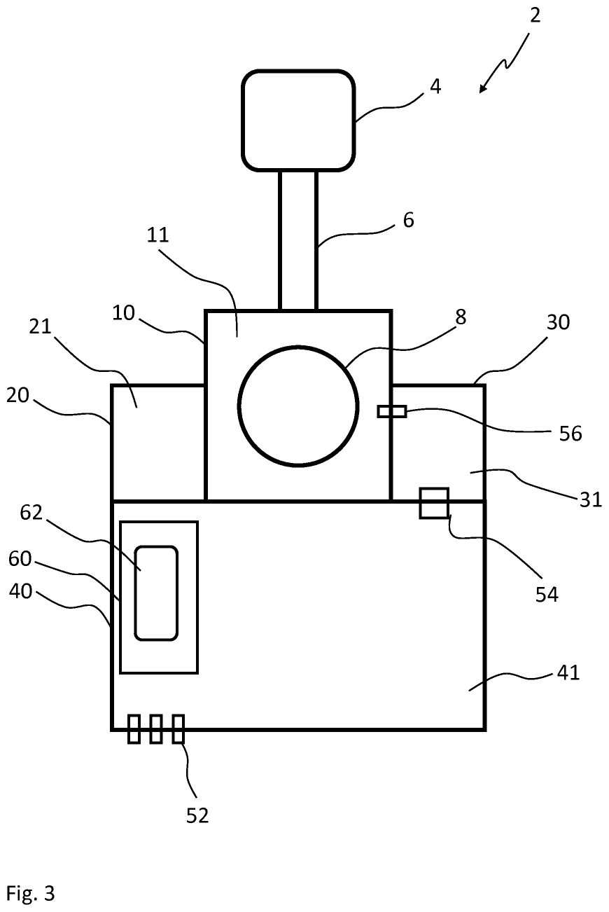

FIG. 3 shows a modification or more detailed view of the ALD apparatus of FIG. 1. The instrumentation compartment 40 comprises apparatus instrumentation elements 60, 62. In the embodiment of FIG. 3, the apparatus instrumentation elements comprise electric components 62 of the ALD apparatus. The electric components and arranged inside an electric component housing 60. In this embodiment, the apparatus ventilation inlet connections 52 are provided in connection with the electric component housing 60 or in vicinity of the electric component housing 60. Thus, the electric component housing 60 is subjected to the ventilation gas entering the instrumentation compartment 40. Thus, the temperature sensitive electric components 62 are cooled.

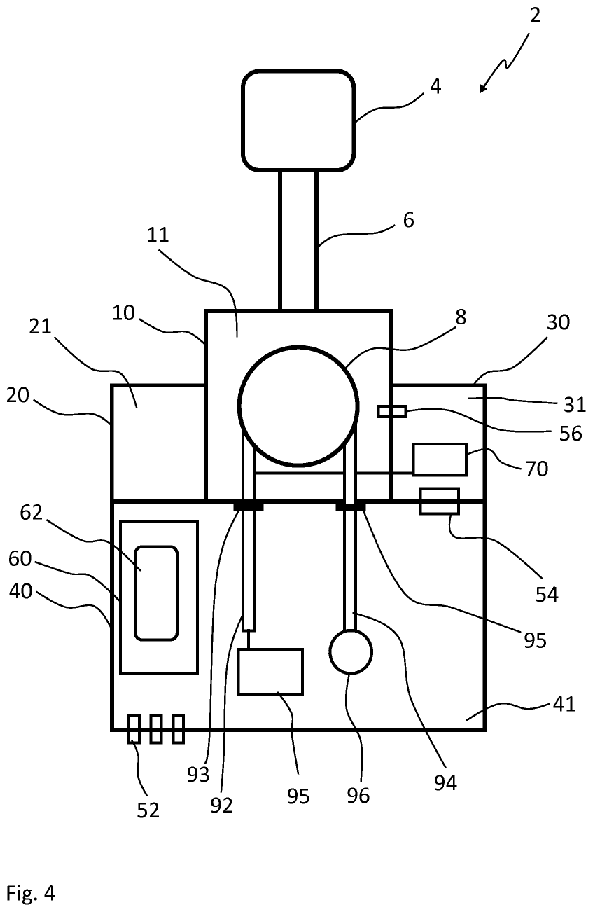

FIG. 4 shows a further modification or more detailed view of the ALD apparatus of FIG. 1. The instrumentation compartment 40 comprises inlet channel 92 to the ALD reactor 8, gas connections 95 for gaseous precursor or carrier gases or purge gases, discharge channel 94 from the ALD reactor 8 and a filter 96 in connection with the discharge channel. Thus, the instrumentation compartment 40 comprises gas instrumentation 92, 95, 94, 96 of the ALD apparatus 2. The inlet channel 92 and the discharge channel 94 extend from the instrumentation compartment 40 to the reactor compartment 10 and further to the ALD reactor 8 in the reactor compartment 10. The inlet channel 92 is provided with a first flange 93 or a first lead-through connection at the instrumentation compartment wall 40 for providing a lead-through connection between the instrumentation compartment 40 and the reactor compartment 10 for the inlet channel 92. Similarly, the discharge channel 94 is provided with a second flange 95 or a second lead-through connection at the instrumentation compartment wall 40 for providing a lead-through connection between the instrumentation compartment 40 and the reactor compartment 10 for the discharge channel 96.

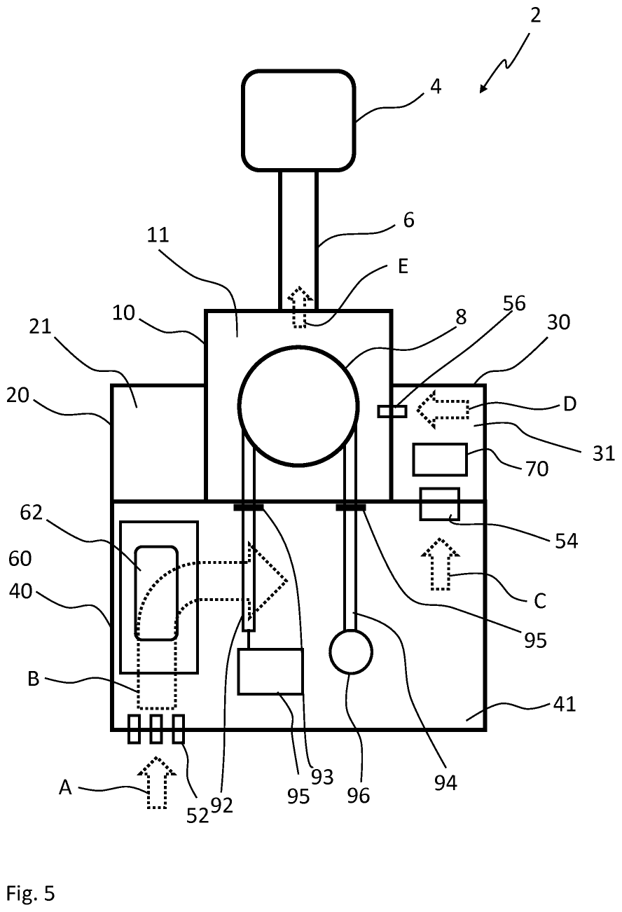

The temperature in the reactor compartment 10 is usually considerably higher than in the instrumentation compartment 40. The temperature increase in the instrumentation compartment 40 is undesirable. The inlet and outlet lead-through connections 93, 95 tend to transport thermal energy from the reactor compartment 10 to the instrumentation compartment 40. Therefore, the apparatus ventilation inlet connections 52 and the first ventilation flow connections 54 are arranged to the instrumentation compartment such that the inlet and outlet lead-through connections 93, 95, and possibly also other gas instrumentation is arranged between the apparatus ventilation inlet connections 52 and the first ventilation flow connections 54 in the instrumentation compartment 40, as shown in FIGS. 4 and 5. Thus, the ventilation gas removes thermal energy efficiently from the instrumentation compartment 40.

FIG. 5 shows schematically ventilation gas flow through the compartments 40, 30 and 10 and thought the outer apparatus casing. The ventilation gas flow is generated with the apparatus ventilation discharge connection 4, 6. The ventilation gas enters the outer apparatus casing via the apparatus ventilation connection 52 inside the instrumentation compartment 40, as shown with arrow A. Then the ventilation gas flows to the first ventilation flow connections 54 provided between the instrumentation compartment 30 and the first precursor supply compartment 30, as shown with arrow B. The instrumentation elements 60, 62, 92, 93, 94, 95, 96 are arranged between the apparatus ventilation connection 52 and the first ventilation flow connections 54. The ventilation gas enters to the first precursor supply compartment 30 via the first ventilation flow connections 54, as shown with arrow C. Then the ventilation gas flows from the first ventilation flow connections 54 to the second ventilation flow connections 56 provided between the first precursor supply compartment 30 and the reactor compartment 10. The precursor source(s) 70 is arranged between the first ventilation flow connections 54 and the second ventilation flow connections 56 inside the first precursor supply compartment 30. Then, the ventilation gas enters to the reactor compartment 10 via the second ventilation flow connections 56, as shown with arrow D. In the reactor compartment 10 the ventilation gas flows from the second ventilation flow connections 56 to the apparatus ventilation discharge connection 4, 6 and further out of the reactor compartment 10 and the outer apparatus casing 10 via the apparatus ventilation discharge connection 4, 6. The ALD reactor 8 is arranged at least partly between the second ventilation flow connections 56 and the apparatus ventilation discharge connection 4, 6 inside the reactor compartment 10.

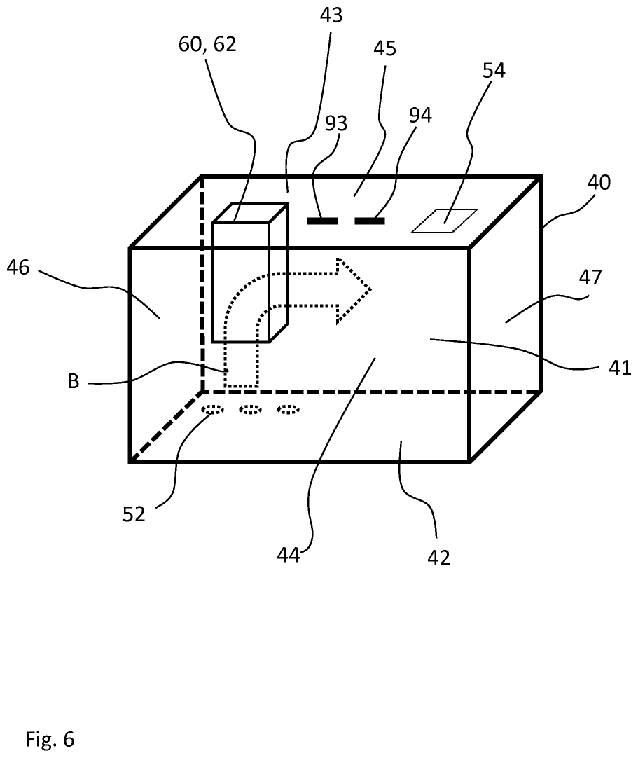

FIG. 6 shows schematically one embodiment of the instrumentation compartment 40. The instrumentation compartment 40 comprises an instrumentation compartment bottom wall 42, an instrumentation compartment top wall 43 and one or more instrumentation compartment side walls 44, 45, 46, 47 extending between the instrumentation compartment bottom wall 42 and the instrumentation compartment top wall 43. The one or more apparatus ventilation inlet connections 52 are provided to the instrumentation compartment bottom wall 42 and the one or more first ventilation flow connections 54 are provided to the instrumentation compartment top wall 43. Therefore, the one or more first ventilation flow connections 54 are arranged in vertical direction above the one or more ventilation inlet connections 52 in the instrumentation compartment 40.

Further, the one or more ventilation inlet connections 52 are arranged in horizontal direction spaced apart from the one or more first ventilation flow connections 54 in the instrumentation compartment 40. As shown in FIG. 6, the one or more ventilation inlet connections 52 and the one or more first ventilation flow connections 54 are arranged in horizontal direction on opposite sides or parts of the instrumentation compartment 40. The one or more ventilation inlet connections 52 are arranged close to or in vicinity of a first side wall 46 and the one or more first ventilation flow connections 54 are arranged close to or in vicinity of a second side wall 47, opposite the first side wall 46. Therefore, the ventilation gas flows through the instrumentation compartment space 41, as shown with arrow B. The instrumentation elements 60, 62, 92, 93, 94, 95, 96 are arranged between the apparatus ventilation connection 52 and the first ventilation flow connections 54 in the instrumentation compartment space 41.

Alternatively, the one or more first ventilation flow connections 54 and/or the one or more apparatus ventilation inlet connections 52 may be provided to the one or more instrumentation compartment side walls 44, 45, 46, 47. Also in this construction, the one or more first ventilation flow connections 54 are preferably arranged in vertical direction above the one or more ventilation inlet connections 52 in the instrumentation compartment 40.

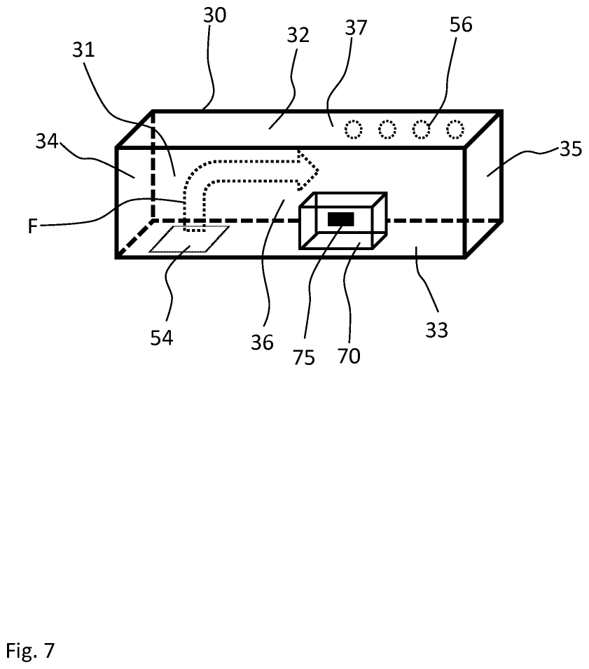

FIG. 7 shows schematically one embodiment of the first precursor supply compartment 30. The first precursor supply compartment 30 comprises a first precursor supply compartment bottom wall 33, a first precursor supply compartment top wall 32 and one or more first precursor supply compartment side walls 34, 35, 36, 37 extending between the first precursor supply compartment bottom wall 33 and the first precursor supply compartment top wall 32. The one or more the first ventilation flow connections 54 are provided to the first precursor supply compartment bottom wall 33 and the one or more second ventilation flow connections 56 are provided to a third precursor supply compartment side wall 37. Further, the one or more second ventilation flow connections 56 are arranged in vertical direction above the one or more first ventilation flow connections 54 in the first precursor supply compartment 30.

Further, the one or more first ventilation inlet connections 54 are arranged in horizontal direction spaced apart from the one or more second ventilation flow connections 56 in the first precursor supply compartment 30. As shown in FIG. 7, the one or more first ventilation flow connections 54 and the one or more second ventilation flow connections 56 are arranged in horizontal direction on opposite sides or parts of the first precursor supply compartment 30. The one or more first ventilation flow connections 54 are arranged close to or in vicinity of a first side wall 34 and the one or more second ventilation flow connections 56 are arranged close to or in vicinity of a second side wall 35, opposite the first side wall 34. Therefore, the ventilation gas flows through the first precursor supply compartment space 31, as shown with arrow F in FIG. 7. The precursor source(s) 70 are arranged between the first ventilation flow connections 54 and the second ventilation flow connections 56 in the first precursor supply compartment space 31.

Alternatively, the one or more first ventilation flow connections 54 may be provided to the one or more first precursor supply compartment side walls 34, 35, 36, 37 and the one or more second ventilation flow connections 56 may be provided to the same or preferably to an opposite side wall 34, 35, 36, 37. Alternatively, the one or more second ventilation flow connections 56 may be provided to first precursor supply compartment top wall 32. Also in these constructions, the one or more second ventilation flow connections 56 are preferably arranged in vertical direction above the one or more first ventilation flow connections 54 in the first precursor supply compartment 30.

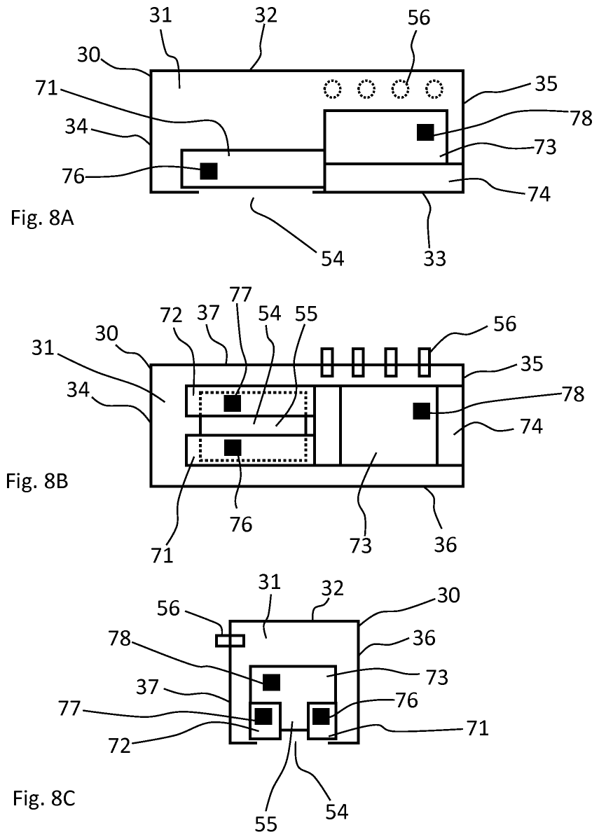

FIGS. 8A, 8B and 8C show schematically one embodiment of the first precursor supply compartment 30 and especially arrangement of precursor supply sources 71, 72, and valve unit 73 in the first precursor supply compartment 30.

FIG. 8A shows schematically a side view of the first precursor supply compartment 30. Inside the first precursor supply compartment 30 there are a first precursor source 71, second precursor source 72 and the valve unit 73. The precursor sources 71, 72 and connected with precursor lines to the valve unit 73. The valve unit 73 comprises valves for supplying precursors to the ALD reactor 8. The valve unit 73 is connected with precursor line(s) to the inlet channel 92 for supplying the precursors to the ALD reactor 8, as shown in FIG. 4.

The first precursor source 71 is provided with a first precursor heart 76, or the first precursor supply compartment 30 is provided with the first precursor heater 76 for heating the first precursor source 71. The second precursor source 72 is provided with a second precursor heart 77, or the first precursor supply compartment 30 is provided with the second precursor heater 77 for heating the second precursor source 72, as shown in FIGS. 8B and 8C.

The valve unit 73 comprises valve heater 78 for heating the valve unit 73. The valve unit 73 is heated with the valve heater 78 to temperature higher than the operating temperature of the precursor sources 71, 72 such that increasing temperature gradient towards the ALD reactor is achieved.

The first and second precursor source 71, 72 are arranged spaced apart from each other such that a flow gap 55 is provided between the two first precursor sources 71, 72. The flow gap 55, and the first and second precursor sources 71, 72 are arranged above the first ventilation flow connections 54. The flow gap 55, and the first and second precursor sources 71, 72 may also be arranged adjacent to, opposite of in the vicinity of the first ventilation flow connections. Thus, the ventilation gas entering the first precursor supply compartment 30 flows between the first and second precursor sources 71, 72 in the flow gap 55. This enables thermally separating the first and second precursor sources 71, 72 from each other.

The first and second precursor sources 71, 72 are closer to the one or more first flow connections 54 than the valve unit 73. The valve unit 73 is closer to the one or more second flow connections 56 than the first and second precursor sources 71, 72, the first and second precursor sources 71, 72 comprising precursor heaters 76, 77 and the valve unit 73 comprising valve heaters 78, respectively.

Further, the valve unit 73 is arranged at least partly above or higher than the first and second precursor sources 71, 72 in vertical direction inside the first precursor supply compartment 30. This enhances ventilation gas flow by utilizing natural convection.

As may be seen form FIGS. 8A and 8C, the second ventilation flow connections 56 are arranged above or higher than the first and second precursor sources 71, 72 and the valve unit 72 in vertical direction inside the first precursor supply compartment 30. Also this enhances ventilation gas flow by utilizing natural convection.

The first and second precursor sources 71, 72 and the valve unit 72 are further provided between the first and second flow connections 54, 56.

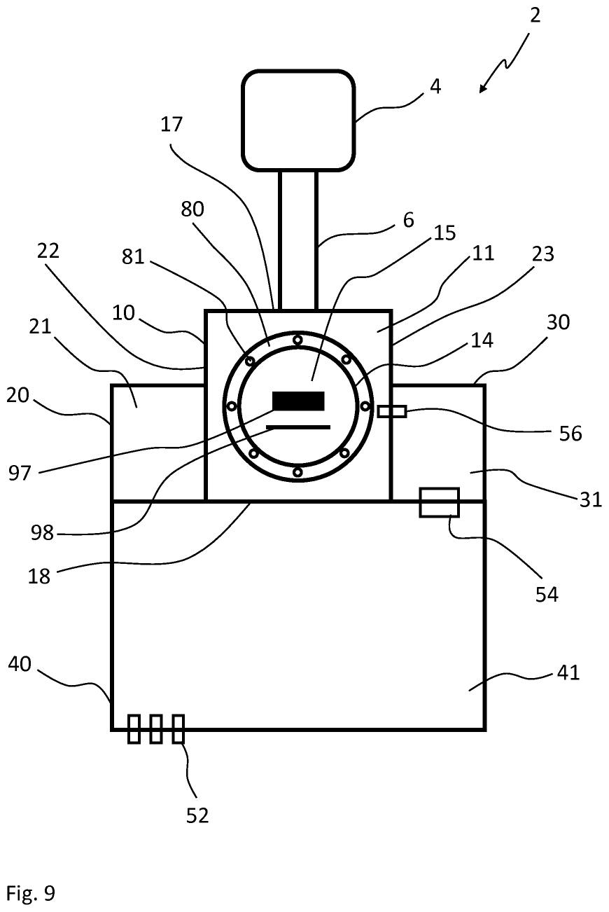

FIG. 9 shows another embodiment, in which the reactor compartment 10 comprises a reactor ventilation inlet connection 80, 81 arranged to provide ventilation gas into the reactor compartment 10 and to the outer apparatus casing 10, 20, 30, 40 directly from outside of the outer apparatus casing 10, 20, 30, 40. The reactor ventilation inlet connection 80, 81 comprises reactor inlet openings or channels 81 open to the inside of the reactor compartment 10. Thus, ventilation gas enters the reactor compartment from the first precursor supply compartment through the second ventilation flow connections 56 and through the reactor ventilation inlet connection 80, 81.

The ALD reactor 8 comprises a vacuum chamber 14 and a reactor chamber 97 arranged inside the vacuum chamber 14. The ALD reactor further comprises reactor heater 98 provided inside the vacuum chamber 14 in space between the vacuum chamber 14 and the reactor chamber 97. The reactor heater 98 heats the reactor chamber 97 by radiation heating.

The door 15 is arranged form side of the reactor compartment and the door for the vacuum chamber 14. The door 15 is arranged against the reactor flange 12. The reactor door forms the front end of the vacuum chamber 14 and the vacuum chamber further comprises back wall 13 at the opposite end of the vacuum chamber 14.

In the embodiment of FIG. 10, the atomic layer deposition reactor 8 comprises the reactor door or reactor door assembly 15 arranged to form at least part of one side wall 15 of the reactor compartment 10. The door assembly 15 comprises the reactor ventilation inlet connection 80, 81 arranged to provide ventilation gas into the reactor compartment 10 and to the outer apparatus casing 10, 20, 30, 40 from outside of the outer apparatus casing 10, 20, 30, 40. The reactor ventilation inlet connection 80, 81 or reactor inlet openings or channels 81 are provided around the reactor door 15 or in vicinity of the reactor door 15 to a ventilation flange 80 provided in connection with the reactor door 15. Alternatively, the reactor inlet openings or connections 81 may be provided to a side wall of the reactor compartment 10. There are reactor inlet openings or connections 81 below the reactor door 15 and above the reactor door 15 and also on the side of the reactor door 15 for supplying ventilation gas around the vacuum chamber 14 inside the reactor compartment 10.

The reactor compartment 10 comprises a reactor compartment bottom wall 18, a reactor compartment top wall 17 and one or more reactor compartment side walls 15, 19, 22, 23 extending between the reactor compartment bottom wall 18 and the reactor compartment top wall 17, as shown in figured 9 and 10. The one or more the second ventilation flow connections 56 are provided to a first reactor compartment side wall 23 and the apparatus ventilation discharge connection 4, 6 provided to the reactor compartment top wall 17. Further, the apparatus ventilation discharge connection 4, 6 is arranged in vertical direction above the one or more second ventilation flow connections 56 and the reactor inlet openings or connections 81 in the reactor compartment 10.

Further, the one or more reactor inlet openings or connections 81 are arranged in horizontal direction spaced apart from the apparatus ventilation discharge connection 4, 6 in the reactor compartment 10. As shown in FIG. 10, the one or more reactor inlet openings or connections 81 and apparatus ventilation discharge connection 4, 6 are arranged in horizontal direction on opposite ends of the reactor compartment 30. The one or more reactor inlet openings or connections 81 are arranged to the front end side wall or door of the reactor compartment 10 and apparatus ventilation discharge connection 4, 6 is arranged at a back end side wall 19 of the reactor compartment. Thus, the ventilation gas enters the reactor compartment 10 via the one or more reactor inlet openings or connections 81, as shown with arrow G. There is a flow space 16 between the reactor compartment walls and the vacuum chamber 14 and the ventilation gas flows in the flow space 16 along the ALD reactor 8 or vacuum chamber towards the apparatus ventilation discharge connection 4, 6, as shown with arrow H, and is discharged from the reactor compartment 10 and the outer apparatus casing via the apparatus ventilation discharge connection 4, 6, as shown with arrow E.

Accordingly, the reactor ventilation inlet connection 80, 81 is arranged in horizontal direction spaced apart from the apparatus ventilation discharge connection 4, 6 in the reactor compartment 10. Further, the ALD reactor 8 or the vacuum chamber is arranged between the one or more reactor inlet openings or connections 81 and apparatus ventilation discharge connection 4, 6 in the reactor compartment 10.

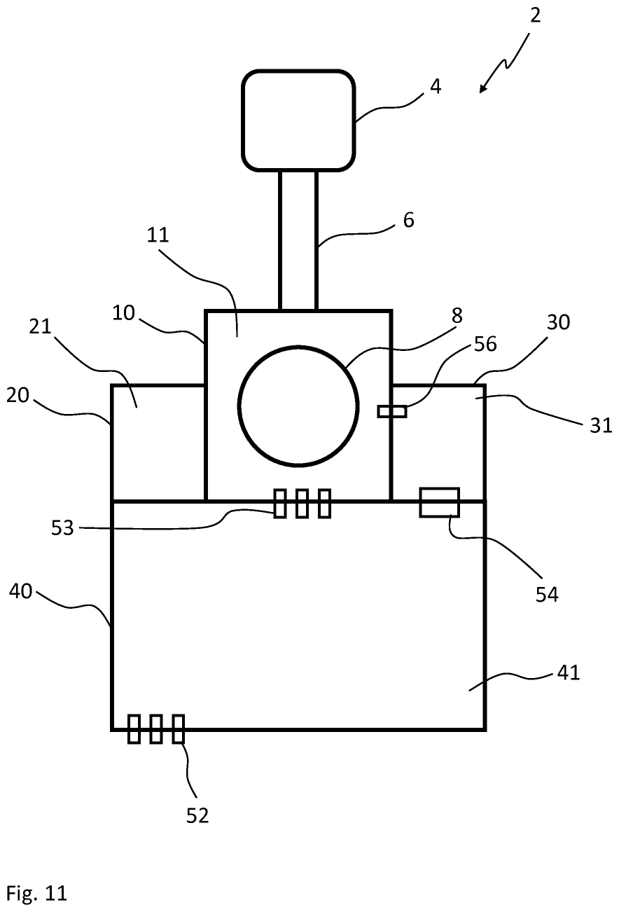

FIG. 11 shows an alternative embodiment, in which the instrumentation compartment 40 further comprises one or more third ventilation flow connections 53 arranged to discharge ventilation gas from the instrumentation compartment 40. The one or more third ventilation flow connections 53 are open to the instrumentation compartment space 41 and in fluid communication with the apparatus ventilation discharge connection 4, 6. Thus, the suction or vacuum provided by the apparatus ventilation discharge connection generates a ventilation gas flow inside and through the instrumentation compartment 40 from the apparatus ventilation inlet connection(s) 52 to the one or more third ventilation flow connections 53.

The one or more third ventilation flow connections 53 may be openings or channels provided to the instrumentation compartment or the instrumentation compartment walls 40 and open to the instrumentation compartment space 41.

As shown in FIG. 11, the reactor compartment 10 comprises the third ventilation flow connections 53. Thus, the third ventilation flow connections 53 are provided between the instrumentation compartment 40 and the reactor compartment 10. Thus, the third ventilation flow connections 53 are open to the reactor compartment 10 and also to the instrumentation compartment 40.

Therefore, the ventilation gas flows from the instrumentation compartment 40 to the reactor compartment 10 through the third ventilation flow connections 53. The third ventilation flow connections 53 are arranged in flow connection with the apparatus ventilation inlet connections 52 and with the apparatus ventilation discharge connection 4, 6.

The third ventilation flow connections 53 may be formed as openings or channels between the instrumentation compartment 30 and the reactor compartment 10 such that the third ventilation flow connections 53 are open to the instrumentation compartment space 41 and the reactor compartment space 11. Accordingly, the third ventilation flow connections 53 provide a flow path between the instrumentation compartment 40 and the reactor compartment 10.

In one embodiment, the instrumentation compartment 40 and the reactor compartment 10 have a common compartment wall, as shown in FIG. 11, and the third ventilation flow connections 53 are provided to the common compartment wall. Alternatively, the one or more third ventilation flow connections 53 may be provided as channels extending between the instrumentation compartment wall 40 and the reactor compartment wall 10.

Further, it should be noted that the instrumentation compartment 40 may be omitted. Thus, the first ventilation flow openings and possible third ventilation flow openings 53 from the apparatus ventilation inlet connections.

The invention has been described above with reference to the examples shown in the figures. However, the invention is in no way restricted to the above examples but may vary within the scope of the claims.

1.-16. (canceled)

17. An atomic layer deposition apparatus for processing substrates according to principles of atomic layer deposition, the apparatus comprising:
an atomic layer deposition reactor;
one or more precursor supply sources connected to the atomic layer deposition reactor;
an outer apparatus casing, the atomic layer deposition reactor and the one or more precursor sources being arranged inside the outer apparatus casing;
an apparatus ventilation discharge connection arranged to discharge ventilation gas from inside of the outer apparatus casing; and
one or more apparatus ventilation inlet connections provided to the outer apparatus casing and arranged to provide ventilation gas into the outer apparatus casing,
wherein:
the outer apparatus casing comprises a reactor compartment comprising the atomic layer deposition reactor provided inside the reactor compartment;
the outer apparatus casing comprises a first precursor supply compartment comprising one or more precursor sources provided inside the first precursor supply compartment;
one or more first ventilation flow connections provided to the first precursor supply compartment arranged to provide ventilation gas into the first precursor supply compartment;
one or more second ventilation flow connections arranged between the first precursor supply compartment and the reactor compartment and arranged to discharge ventilation gas from the first precursor supply compartment and provide ventilation gas from the first precursor supply compartment to the reactor compartment; and
the apparatus ventilation discharge connection is provided to the reactor compartment and arranged to discharge ventilation gas from the reactor compartment and from inside of the outer apparatus casing.

18. The apparatus according to claim 17, wherein:
the one or more second ventilation flow connections are arranged in vertical direction above the one or more first ventilation flow connections in the first precursor supply compartment; or
the first precursor supply compartment is provided with a first precursor supply compartment bottom wall, a first precursor supply compartment top wall and one or more first precursor supply compartment side walls extending between the first precursor supply compartment bottom wall and the first precursor supply compartment top wall, and that the one or more first ventilation flow connections are arranged to the first precursor supply compartment bottom wall and the one or more second ventilation flow connections are arranged to first precursor supply compartment top wall; or
the first precursor supply compartment is provided with a first precursor supply compartment bottom wall, a first precursor supply compartment top wall and one or more first precursor supply compartment side walls extending between the first precursor supply compartment bottom wall and the first precursor supply compartment top wall, and that the one or more first ventilation flow connections are arranged to the first precursor supply compartment bottom wall and the one or more second ventilation flow connections are arranged to the one or more first precursor supply compartment side walls.

19. The apparatus according to claim 17, wherein the reactor compartment comprises one or more ventilation inlet flow connections arranged to provide ventilation gas into the reactor compartment.

20. The apparatus according to claim 19, wherein:
the apparatus ventilation discharge connection is arranged in vertical direction above the one or more ventilation inlet flow connections in the reactor compartment; or
the reactor compartment comprises a reactor compartment top wall, and the apparatus ventilation discharge connection is provided to the reactor compartment top wall and in vertical direction above the one or more ventilation inlet flow connections; or
the reactor compartment comprises a reactor compartment bottom wall, a reactor compartment top wall, and one or more reactor compartment side walls extending between the reactor compartment bottom wall and reactor compartment top wall, and that the apparatus ventilation discharge connection is provided to the reactor compartment top wall and the one or more ventilation inlet flow connections are provided to the reactor compartment bottom wall; or
the reactor compartment comprises a reactor compartment bottom wall, a reactor compartment top wall, and one or more reactor compartment side walls extending between the reactor compartment bottom wall and reactor compartment top wall, and that the apparatus ventilation discharge connection is provided to the reactor compartment top wall and the one or more ventilation inlet flow connections are provided to the one or more reactor compartment side walls.

21. The apparatus according to claim 19, wherein:
the one or more second ventilation flow connections of the first precursor supply compartment form the one or more ventilation inlet flow connections of the reactor compartment such that ventilation gas is arranged to flow from the first precursor supply compartment to the reactor compartment; or
the first precursor supply compartment and the reactor compartment are connected to each other, and that the one or more second ventilation flow connections of the first precursor supply compartment form one or more ventilation inlet flow connections of the reactor compartment such that ventilation gas is arranged to flow from the first precursor supply compartment to the reactor compartment.

22. The apparatus according to claim 21, wherein the one or more first ventilation flow connections of the first precursor supply compartment are arranged to form the one or more ventilation inlet connections of the apparatus and arranged to provide ventilation gas into the outer apparatus casing and into the first precursor supply compartment.

23. The apparatus according to claim 17, wherein the outer apparatus casing comprises an instrumentation compartment comprising apparatus instrumentation elements, the instrumentation compartment comprising the one or more ventilation inlet connections arranged to provide ventilation gas into the outer apparatus casing and into the instrumentation compartment and one or more ventilation outlet flow connections arranged to discharge ventilation gas from the instrumentation compartment.

24. The apparatus according to claim 23, wherein:
the one or more ventilation outlet flow connections are arranged in vertical direction above the one or more ventilation inlet connections in the instrumentation compartment; or
the instrumentation compartment comprises an instrumentation compartment bottom wall, and the one or more ventilation inlet connections are provided to the instrumentation compartment bottom wall, the one or more ventilation outlet flow connections being arranged in vertical direction above the one or more ventilation inlet connections in the instrumentation compartment; or
the instrumentation compartment comprises an instrumentation compartment bottom wall, an instrumentation compartment top wall and one or more instrumentation compartment side walls extending between the instrumentation compartment bottom wall and the instrumentation compartment top wall, and that the one or more ventilation inlet connections are provided to the instrumentation compartment bottom wall and the one or more ventilation outlet flow connections are provided to the instrumentation compartment top wall; or
the instrumentation compartment comprises an instrumentation compartment bottom wall, an instrumentation compartment top wall and one or more instrumentation compartment side walls extending between the instrumentation compartment bottom wall and the instrumentation compartment top wall, and that the one or more ventilation inlet connections are provided to the instrumentation compartment bottom wall and the one or more ventilation outlet flow connections are provided to the one or more instrumentation compartment side walls.

25. The apparatus according to claim 23, wherein:
one or more ventilation outlet flow connections of the instrumentation compartment form one or more first ventilation flow connections of the first precursor supply compartment such that ventilation gas is arranged to flow from the of the instrumentation compartment to the first precursor supply compartment; or
instrumentation compartment and the first precursor supply compartment are connected to each other, and that one or more ventilation outlet flow connections of the instrumentation compartment form one or more first ventilation flow connections of the first precursor supply compartment such that ventilation gas is arranged to flow from the of the instrumentation compartment to the first precursor supply compartment.

26. The apparatus according to claim 23, wherein:
one or more ventilation outlet flow connections of the instrumentation compartment form one or more ventilation inlet flow connections of the reactor compartment such that ventilation gas is arranged to flow from the of the instrumentation compartment to the reactor compartment; or
instrumentation compartment and the reactor compartment are connected to each other, and that one or more ventilation outlet flow connections of the instrumentation compartment form one or more first ventilation inlet flow connections of the reactor compartment such that ventilation gas is arranged to flow from the of the instrumentation compartment to the reactor compartment.

27. The apparatus according to claim 17, wherein the outer apparatus casing comprises the instrumentation compartment enclosing apparatus instrumentation elements, the first precursor supply compartment enclosing one or more precursor sources and the reactor compartment enclosing the atomic layer deposition reactor; and that:
the one or more apparatus ventilation inlet connections are provided to the instrumentation compartment and arranged to provide ventilation gas into the instrumentation compartment and inside the outer apparatus casing;
one or more first ventilation flow connections are arranged between the instrumentation compartment and the first precursor supply compartment and arranged to provide ventilation gas flow from the instrumentation compartment to the first precursor supply compartment;
one or more second ventilation flow connections are arranged between the first precursor supply compartment and the reactor compartment and arranged to provide ventilation gas flow from the first precursor supply compartment to the reactor compartment; and
the apparatus ventilation discharge connection is arranged to the reactor compartment and arranged to discharge ventilation gas from reactor compartment and from inside of the outer apparatus casing.

28. The apparatus according to claim 27, wherein in the apparatus the one or more first ventilation flow connections are arranged in vertical direction above the one or more apparatus ventilation inlet connections, the one or more second ventilation flow connections are arranged in vertical direction above the one or more first ventilation flow connections, and the apparatus ventilation discharge connection is arranged in vertical direction above the one or more second ventilation flow connections.

29. The apparatus according to claim 17, wherein:
the first precursor supply compartment comprises at least one precursor heater arranged to heat the precursor source inside the first precursor supply compartment; or
the reactor compartment or the atomic layer deposition reactor comprises at least one reactor heater arranged to heat the atomic layer deposition reactor inside the reactor compartment; or
the first precursor supply compartment comprises at least one precursor heater arranged to heat the precursor source inside the first precursor supply compartment, and the reactor compartment or the atomic layer deposition reactor comprises at least one reactor heater arranged to heat the atomic layer deposition reactor inside the reactor compartment.

30. The apparatus according to claim 17, wherein:
the first precursor supply compartment comprises two first precursor sources arranged spaced apart from each other such that a flow gap is provided between the two first precursor sources, each of the two first precursor sources comprising precursor heater; or
the first precursor supply compartment comprises a first precursor source and a valve unit, and that first precursor source is closer to the one or more first flow connections than the valve unit, and the valve unit is closer to the one or more second flow connections than the first precursor source, the first precursor source comprising precursor heater and the valve unit comprising valve heater, respectively; or
the first precursor supply compartment comprises first and second precursor sources arranged spaced apart from each other such that a flow gap is provided between the first and second precursor sources, and a valve box, and that the first and second precursor sources are closer to the one or more first flow connections than the valve unit, and the valve unit is closer to the one or more second flow connections than the first and second precursor sources, the first and second precursor sources comprising precursor heaters and the valve unit comprising valve heaters, respectively.

31. The apparatus according to claim 19, wherein:
the reactor compartment comprises a reactor ventilation inlet arrangement arranged to provide ventilation gas into the reactor compartment and to the outer apparatus casing from outside of the outer apparatus casing; or
the atomic layer deposition reactor comprises a reactor door assembly arranged to form at least part of one side wall of the reactor compartment, and that the door assembly comprises a reactor ventilation inlet connection arranged to provide ventilation gas into the reactor compartment and to the outer apparatus casing from outside of the outer apparatus casing.

32. The apparatus according to claim 19, wherein the outer apparatus casing comprises one or more of the following:
the one or more ventilation inlet connections are arranged in horizontal direction spaced apart from the one or more ventilation outlet flow connections in the instrumentation compartment;
one or more first ventilation flow connections are arranged in horizontal direction spaced apart from the one or more second ventilation flow connections in the of the first precursor supply compartment;
one or more ventilation inlet flow connections are arranged in horizontal direction spaced apart from the apparatus ventilation discharge connection in the reactor compartment; and
the reactor ventilation inlet connection is arranged in horizontal direction spaced apart from the apparatus ventilation discharge connection in the reactor compartment.
